(19) United States
(12) Patent Application Publication
(10) Pub. No.: US 2016/0099550 A1
(43) Pub. Date: Apr. 7, 2016

(54) LASER APPARATUS AND INFORMATION ACQUISITION APPARATUS USING THE SAME

(71) Applicant: CANON KABUSHIKI KAISHA, Tokyo (JP)

(72) Inventor: Kohei Okamoto, Yokohama-shi (JP)

(21) Appl. No.: 14/869,212

(22) Filed: Sep. 29, 2015

(30) Foreign Application Priority Data
Oct. 1, 2014 (JP) 2014-203271

(51) Int. Cl. H01S 5/40; G01J 1/42; H01S 5/42; H01S 5/04; H01S 5/14; H01S 5/183

(52) U.S. Cl. CPC H01S 5/4075; H01S 5/14; H01S 5/183; H01S 5/4062; H01S 5/423; H01S 5/041; G01J 1/4257

(57) ABSTRACT

A laser apparatus includes an active medium, a first reflection portion, a second reflection portion, a first laser array including a plurality of semiconductor lasers, a third reflection portion configured to reflect at least part of light emitted from the first laser array and transmitted through the active medium, and a fourth reflection portion configured to transmit at least part of light emitted from the first laser array, and to reflect at least part of light reflected by the third reflection portion and transmitted through the active medium. The fourth reflection portion is disposed across the plurality of semiconductor lasers including respective light-emitting regions of the plurality of semiconductor lasers of the first laser array.

### BACKGROUND OF THE INVENTION

1. Field of the Invention

The present invention relates to a laser apparatus and an information acquisition apparatus using the same.

2. Description of the Related Art

Laser apparatuses in which an active medium produces laser oscillation by photoexcitation are well known. To increase the laser output of a laser apparatus, excitation light emitted from an excitation light source needs to be efficiently absorbed by the active medium.

Japanese Patent Application Laid-Open No. 2000-101169 discusses a configuration in which excitation light emitted from semiconductor lasers disposed in an array goes and returns many times in an active medium and the absorption efficiency of the excitation light with respect to the active medium is increased. Specifically, in the laser apparatus discussed in Japanese Patent Application Laid-Open No. 2000-101169, a high-reflection coating having high reflectance with respect to excitation light is applied to an emission edge excluding a light-emitting region of the semiconductor lasers, and a reflection mirror configured to reflect excitation light is disposed on a side opposite to the semiconductor lasers with respect to the active medium. The high-reflection coating and the reflection mirror reflect the excitation light many times so that the excitation light goes and return many times in the active medium.

According to Japanese Patent Application Laid-Open No. 2000-101169, however, the high-reflection coating is not applied to the light-emitting region at the emission edge of the semiconductor lasers. Thus, part the excitation light returns from the light-emitting region to the inside of the semiconductor lasers, making the operation of the semiconductor lasers unstable.

### SUMMARY OF THE INVENTION

The present invention is directed to a laser apparatus that improves the operation stability of a semiconductor laser being an excitation light source, and the absorption efficiency of an active medium with respect to excitation light.

According to an aspect of the present invention, a laser apparatus includes an active medium, a resonance unit including a first reflection portion and a second reflection portion which are configured to resonate light emitted from the active medium, a first laser array including a plurality of semiconductor lasers configured to emit light for exciting the active medium from a direction different from a resonance direction of the resonance unit, a third reflection portion configured to reflect at least part of light emitted from the first laser array and transmitted through the active medium, and a fourth reflection portion disposed between the active medium and the first laser array and configured to transmit at least part of light emitted from the first laser array, and to reflect at least part of light reflected by the third reflection portion and transmitted through the active medium, wherein the fourth reflection portion is disposed across the plurality of semiconductor lasers including respective light-emitting regions of the plurality of semiconductor lasers of the first laser array.

Further features of the present invention will become apparent from the following description of exemplary embodiments with reference to the attached drawings.

### BRIEF DESCRIPTION OF THE DRAWINGS

FIGS. 1A and 1B are diagrams each illustrating an example of a laser apparatus according to a first exemplary embodiment.

FIG. 2 is a diagram illustrating another example of a laser apparatus according to a second exemplary embodiment.

FIGS. 3A and 3B are diagrams each illustrating another example of a laser apparatus according to a third exemplary embodiment.

FIG. 4A and 4B are diagrams each illustrating another example of a laser apparatus according to a fourth exemplary embodiment.

FIG. 5 is a block diagram illustrating an example of a photoacoustic apparatus including a laser apparatus according to a fifth exemplary embodiment.

FIG. 6 is a diagram illustrating an example of a laser apparatus according to Example 2.

### DESCRIPTION OF THE EMBODIMENTS

A laser apparatus according to an exemplary embodiment of the present invention includes an active medium and a resonance unit (optical cavity) including first and second reflection portions configured to resonate light emitted from the active medium. The laser apparatus includes, as an excitation light source, a first laser array including a plurality of semiconductor lasers configured to emit light for exciting the active medium from a direction different from a resonance direction of the resonance unit.

At least part of the light emitted from the semiconductor lasers is absorbed by the active medium to excite the active medium. By this excitation, a population inversion is achieved in the active medium. Meanwhile, spontaneously-emitted light in the active medium that propagates in the resonance direction and has a wavelength corresponding to the length of the resonance unit goes and returns in the active medium between the first and second reflection portions. This is followed by stimulated emission in the active medium, so that the light that propagates in the resonance direction and has a wavelength corresponding to the length of the resonance unit is amplified to cause laser oscillation.

Meanwhile, part of the light emitted from the semiconductor lasers is not sufficiently absorbed in the active medium and is thus transmitted through the active medium. To reflect the light emitted from the plurality of semiconductor lasers and transmitted through the active medium, the laser apparatus includes a third reflection portion. Further, part of the light reflected by the third reflection portion is not absorbed by the active medium and is thus returned to the semiconductor lasers. To reflect the returned light again, a fourth reflection portion is disposed between the active medium and the first laser array. The foregoing configuration allows the light emitted from the first laser array to be reflected many times between the third reflection portion and the fourth reflection portion, so that the light emitted from the semiconductor lasers can be efficiently absorbed by the active medium.

Further, the fourth reflection portion is disposed across the plurality of semiconductor lasers including respective light-emitting regions of the plurality of semiconductor lasers of the first laser array. The laser array has a configuration in which a plurality of semiconductor lasers is disposed within the same plane or in the same direction, so that the plurality of semiconductor lasers in the laser array emits light in the same direction. In other words, the fourth reflection portion is formed across the entire surfaces of the emission edges of the plurality of semiconductor lasers disposed within the same plane or in the same direction. This configuration facilitates the manufacturing because the reflection portion can be uniformly formed on the surfaces of the plurality of semiconductor lasers. Further, since the fourth reflection portion is formed also on the light-emitting regions, the amount of light returning to the insides of the semiconductor lasers is reduced, so that the operation of the semiconductor lasers can be prevented from becoming unstable.

Edge emitting lasers, vertical cavity surface emitting lasers (VCSELs), or external cavity lasers can be used as the semiconductor lasers. The point that the plurality of semiconductor lasers constituting the laser array has the same structure is advantageous from the point of view that the semiconductor lasers can be two-dimensionally or one-dimensionally disposed or can be collectively formed.

The plurality of semiconductor lasers disposed within the same plane may constitute a laser bar in which emission edges of a plurality of edge emitting lasers are one-dimensionally disposed, or a laser bar stack in which emission edges of a plurality of edge emitting lasers are two-dimensionally disposed. Further, the plurality of semiconductor lasers disposed within the same plane may constitute a VCSEL array.

The term “light-emitting region” refers to a region of an emission edge of a semiconductor laser where light is emitted. For example, in the case of an edge emitting laser, light is emitted not from an entire region of an emission edge of an active layer but from a part of the emission edge due to the current confinement structure. In this case, the region that is the part of the emission edge of the active layer where light is emitted is referred to as a light-emitting region. This also applies to the case of a surface emitting laser. In the present exemplary embodiment, the fourth reflection portion is disposed across the entire region of the emission edge of the first laser array including the light-emitting regions of the semiconductor lasers.

The term “reflection portion” refers to a portion where a high-reflection coating is applied to a surface of a reflection mirror or an active medium. Further, the reflection mirror may be composed of a single component such as a metal having high reflectance or may have a configuration in which a high-reflection coating is applied to a surface of a certain component. Further, the reflection mirror may include a distributed Bragg reflector (DBR) including a multilayer in which a high refractive index layer having a relatively high refractive index and a low refractive index layer having a relatively low refractive index are alternately stacked.

The phrase “between the active medium and the first laser array” refers to between a surface of the active medium on the first laser array side and a surface of the reflection portion constituting the emission edges of the semiconductor lasers of the first laser array that is opposite to a surface facing the active medium. For example, not only the reflection portion located closer to the active medium than the emission edges of the semiconductor lasers are located but also the reflection portion constituting the emission edges of the semiconductor lasers constitute the reflection portion between the active medium and the first laser array.

The following crystals can be used as the active medium. More specifically, Cr³⁺:BeAl₂O₄ (alexandrite) crystal, Cr³⁺:LiSrAlF₆ (LiSAF) crystal, Cr³⁺:LiCalAlF₆ (LiCAF) crystal, or Cr³⁺:LiSrGaF₆ (LiGAF) crystal can be used. Further, Nd³⁺:Y₃Al₅O₁₂ (Nd:YAG) crystal, Nd:YVO₄ crystal, Nd:GdVO₄ crystal, Yb³⁺:Y₃Al₅O₁₂ (Nd:YAG) crystal, Yb:YVO₄ crystal, or Cr⁴⁺:Y₃Al₅O₁₂ (Cr:YAG) crystal can also be used. Further, Ti:Al₂O₃ (titanium-sapphire) crystal or Cr³⁺:Al₂O₃ (ruby) crystal can also be used. The laser oscillation wavelengths of the foregoing crystals are in the visible range to the near-infrared range. The active medium may have a rod (cylindrical) shape having a round or circular cross-section, or a slab shape having a rectangular cross-section.

As to the semiconductor lasers, semiconductor lasers having an oscillation wavelength overlapping the absorption wavelength range of the active medium are used. For example, an alexandrite crystal has an absorption wavelength range with a central absorption wavelength of about 420 nm, so it is preferable to use a gallium nitride (GaN) based semiconductor laser having an oscillation wavelength of about 400 nm to about 450 nm. Further, an alexandrite crystal also has an absorption wavelength range with a central absorption wavelength of about 580 nm to about 690 nm, so a gallium arsenide (GaAs) based semiconductor laser having an oscillation wavelength in the wavelength range can also be used. Further, Nd:YAG crystal, Nd:YVO₄ crystal, and Nd:GdVO₄ crystal have an absorption wavelength of about 808 nm or about 940 nm. Thus, it is preferable to use a GaAs based semiconductor laser with an oscillation wavelength of about 808 nm or about 940 nm, or an indium phosphide (InP) based semiconductor laser with an oscillation wavelength of about 940 nm. Further, the absorption wavelength of Yb:YAG crystal is about 940 nm, so it is preferable to use a GaAs based semiconductor laser. Further, it is also possible to use a second harmonic by use of a non-linear optical crystal to emit light of a necessary oscillation wavelength. Further, a titanium-sapphire crystal has an absorption wavelength range with a central absorption wavelength of about 490 nm, so it is preferable to use an indium gallium nitride (InGaN) based semiconductor laser.

In a case where the active medium has a rod shape, it is desirable to position the first laser array in such a manner that light emitted from the semiconductor lasers enters the active medium from a direction perpendicular to a long axis direction of the rod shape. Further, in a case where the active medium has a slab shape, it is desirable to position the first laser array in such a manner that light emitted from the semiconductor lasers enters the largest surface of the slab shape.

The following describes laser apparatuses according to exemplary embodiments of the present invention in detail with reference to drawings, but the present invention is not limited to the following exemplary embodiments. Further, the exemplary embodiments can be combined as appropriate.

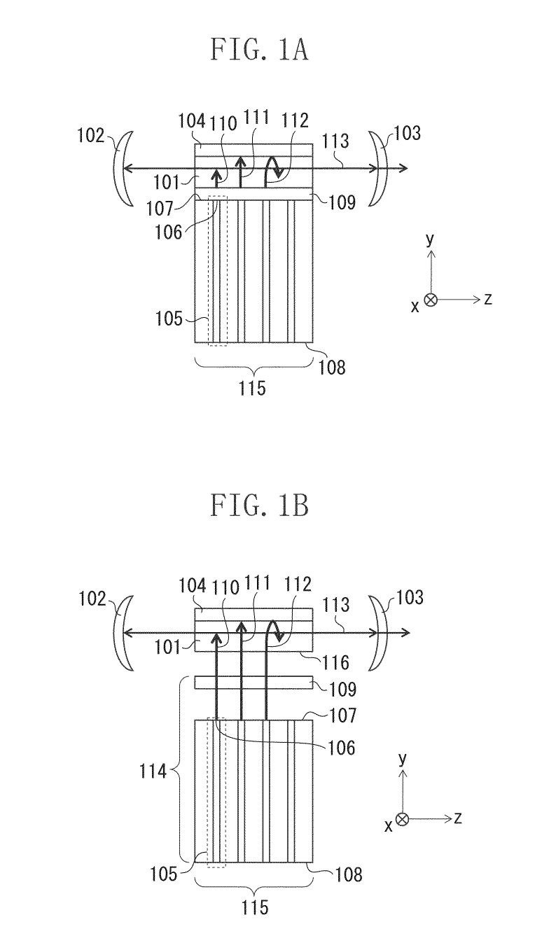

FIG. 1A is a diagram illustrating an example of a laser apparatus according to a first exemplary embodiment. The laser apparatus according to the present exemplary embodiment includes an active medium 101, a first reflection portion 102, and a second reflection portion 103. The first reflection portion 102 and the second reflection portion 103 constitute a resonance unit configured to resonate light 113 emitted from the active medium 101, and the resonance direction is a z-direction. The laser apparatus includes a first laser array 115 including a plurality of semiconductor lasers 105 disposed in the same plane (x-z plane) and configured to emit light 110 for exciting the active medium 101 from a y-direction different from the z-direction, which is the resonance direction. The direction in which light is emitted from each of the plurality of semiconductor lasers 105 is the y-direction. The active medium 101 may have a rod shape of which the long axis direction is the z-direction, or a slab shape which has a large surface on the x-z plane, and of which the thickness direction is the y-direction.

The first reflection portion 102 has a reflectance of 99.9% or higher with respect to a laser oscillation wavelength of light emitted from the active medium 101. The second reflection portion 103 has a reflectance of 30.0% or higher and 99.0% or lower with respect to a laser oscillation wavelength of light emitted from the active medium 101, to emit laser light in the z-direction. The reflectance of the second reflection portion 103 is determined according to the output of laser light to be emitted, etc.

The first laser array 115 is a laser bar stack including the plurality of edge-emitting semiconductor lasers 105. The semiconductor lasers 105 include an active layer (not illustrated). An emission edge 107 and an edge surface 108 sandwiching the active layer constitute a resonator, and light with a specific wavelength amplified by the resonator is emitted as excitation light for exciting the active medium 101, from the emission edge 107 toward the active medium 101 (in the y-direction). The emission edge 107 has a reflectance of 10.0% or higher and 70.0% or lower in the wavelength range of light emitted from the semiconductor lasers 105. The edge surface 108 has a reflectance of 90.0% or higher in the wavelength range of light emitted from the semiconductor lasers 105.

At least part of the light 110 emitted from the semiconductor lasers 105 is absorbed by the active medium 101 and excites the active medium 101, so that the active medium 101 emits light. The emitted light that propagates in the resonance direction (z-direction) and has a wavelength corresponding to the length of the resonance unit goes and returns in the active medium 101 between the first reflection portion 102 and the second reflection portion 103 to cause stimulated emission in the active medium 101. Consequently, the light that propagates in the resonance direction and has a wavelength corresponding to the length of the resonance unit is amplified to cause laser oscillation.

Further, to increase the absorption efficiency of the semiconductor lasers 105 in the active medium 101, the laser apparatus includes a third reflection portion 104 configured to reflect light 111 emitted from the plurality of semiconductor lasers 105 and transmitted through the active medium 101. Further, part of light 112 reflected by the third reflection portion 104 is not absorbed by the active medium 101 and returns to the semiconductor lasers 105. To reflect the light 112 again, a fourth reflection portion 109 is disposed between the first laser array 115 and the active medium 101.

The fourth reflection portion 109 has a function of transmitting at least part of the light 110 emitted from the emission edges 107 of the semiconductor lasers 105 and reflecting part of the light 112 reflected by the third reflection portion 104. Therefore, the fourth reflection portion 109 may also be considered as a semi-transmissive portion or as a semi-reflective portion. However, the term “semi” does not indicate the amount of light transmission or reflection, but it refers only to the fact that portion 109 has a function of transmitting at least part of the light 110 and reflecting part of the light 112. The light 112 has the same wavelength range as the light emitted from the emission edges 107 of the semiconductor lasers 105. Thus, the fourth reflection portion 109 has a function of transmitting at least part of the light emitted from the emission edges 107 of the semiconductor lasers 105 and reflecting part of the light emitted therefrom. Thus, the reflectance of the fourth reflection portion 109 in the wavelength range of the light emitted from the semiconductor lasers 105 is preferably 70.0% or higher and 99.0% or lower. In a case where the reflectance is less than 70.0%, the amount of the reflected light 112 transmitted through the fourth reflection portion 109 becomes excessively large. This decreases the effect of the reflection repeated many times, and the excitation light cannot be efficiently absorbed by the active medium 101. Further, the reflectance higher than 99.0% is not preferable because the amount of the light 110 emitted from light-emitting regions 106 of the semiconductor lasers 105 to the active medium 101 decreases.

The third reflection portion 104 reflects the light 111 emitted from the plurality of semiconductor lasers 105 via the fourth reflection portion 109 and transmitted through the active medium 101. If the reflectance of the third reflection portion 104 is low, the amount of light that is not reflected by the third reflection portion 104 and is transmitted through the third reflection portion 104 increases to decrease the effect of the reflection repeated many times. Thus, the reflectance in the wavelength range of the light emitted from the semiconductor lasers 105 is preferably 90.0% or higher.

Further, the fourth reflection portion 109 is disposed across the plurality of semiconductor lasers 105 including the respective light-emitting regions 106 of the plurality of semiconductor lasers 105 located in the x-z plane. This configuration facilitates the manufacturing because the reflection portion can be formed uniformly on the surfaces of the plurality of semiconductor lasers 105. Further, since the fourth reflection portion 109 is formed also on the light-emitting regions 106, the reflected light 112 is prevented from returning to the inside of the semiconductor lasers 105 via the light-emitting regions 106, so that the operation stability of the semiconductor lasers 105 can be improved.

In FIG. 1A, the third reflection portion 104 is disposed in contact with the active medium 101. The fourth reflection portion 109 is disposed in contact with the emission edges 107 of the plurality of semiconductor lasers 105 and the active medium 101. The configuration illustrated in FIG. 1A, however, is not a limiting example. As illustrated in FIG. 1B, the fourth reflection portion 109 may be disposed at a distance from the emission edges 107 of the plurality of semiconductor lasers 105. Furthermore, the fourth reflection portion 109 may be disposed at a distance from the active medium 101. Further, the third reflection portion 104 may be disposed at a distance from the active medium 101.

It should be noted, however, that normally the light emitted from the first laser array 115 tends to be dispersed in a space with a certain divergence angle. Thus, in a case where the fourth reflection portion 109 is disposed at a distance from the emission edges 107 of the semiconductor lasers 105 and/or the active medium 101, the light that does not enter the active medium 101 may be generated. Further, the light reflected by the third reflection portion 104 and transmitted again through the active medium 101 to return to the fourth reflection portion 109 also has a divergence angle. Thus, each time the light is reflected between the fourth reflection portion 109 and the third reflection portion 104, the amount of the light that escapes from the active medium 101 to the outside increases. To prevent the foregoing situation, a collimator can be provided in the light-emitting regions 106 as discussed in Japanese Patent Application Laid-Open No. 2000-101169, but this complicates the configuration. Accordingly, it is effective to bring the active medium 101 and the fourth reflection portion 109 close to each other, and it is desirable to dispose the third reflection portion 104 and the fourth reflection portion 109 to be in contact with the active medium 101.

Further, there is a possibility that the light 110 emitted from the semiconductor laser 105 is reflected by the emission edges 107 of the semiconductor lasers 105 or a surface 116 of the active medium 101 that faces the semiconductor laser 105, and the emitted light 110 does not enter the active medium 101. Thus, it is desirable to apply an anti-reflection (AR) coating to the emission edges 107 and the surface 116 so as to have high transmittance with respect to the wavelength range of the light 110 emitted from the semiconductor lasers 105.

Further, it is desirable to design the semiconductor lasers 105 by treating the fourth reflection portion 109 as a reflection portion constituting a part of the resonance unit of the semiconductor lasers 105. Thus, in FIG. 1B, it is desirable to design the semiconductor lasers 105 by treating the semiconductor lasers 105 and the fourth reflection portion 109 as an external cavity laser 114. For example, it is desirable to optically design the external cavity laser 114 in such a manner that the edge surface 108, the emission edge 107, and the fourth reflection portion 109 are treated as reflection portions constituting the resonance unit. Further, the reflectance of the fourth reflection portion 109 is preferably higher than the reflectance of the emission edge 107 so as to enable the fourth reflection portion 109 to function as an output reflection mirror constituting the resonator of the semiconductor lasers 105. One example is a method in which the AR coating described above is applied to the emission edge 107. In this case, it is desirable to optically design the edge surface 108 and the fourth reflection portion 109 as reflection portions constituting the resonance unit.

As described above, the first reflection portion 102 has a reflectance of 99.9% or higher with respect to the oscillation wavelength of light emitted by the active medium 101. The first reflection portion 102 can be configured to include a reflection mirror including a DBR or metal. Further, the first reflection portion 102 may be a concave mirror having the shape of a concave surface toward the active medium 101 as illustrated in FIGS. 1A and 1B. Further, the first reflection portion 102 may be a convex mirror having the shape of a convex surface toward the active medium 101, or a reflection mirror in the shape of a flat plate. Further, in the case of using a reflection mirror in the shape of a flat plate as the first reflection portion 102, it is desirable to dispose between the active medium 101 and the first reflection portion 102 a lens having the function of collecting at the active medium 101 the light reflected by the first reflection portion 102.

Further, the first reflection portion 102 may be formed by applying multilayer coating or metal coating directly on the active medium 101. In this case, it is sufficient that the material type, thickness, etc. of the multilayer coating or metal coating are selected so that the first reflection portion 102 has a reflectance of 99.9% or higher with respect to the oscillation wavelength of light emitted by the active medium 101.

The second reflection portion 103 has a reflectance of 30.0% or higher and 99.0% or lower with respect to the oscillation wavelength of light emitted by the active medium 101 so as to extract the light to outside. If this condition is satisfied, the second reflection portion 103 can be configured to include a reflection mirror including a DBR or metal or a metal coating as in the first reflection portion 102. Further, the second reflection portion 103 may have a shape including a concave surface toward the active medium 101 as illustrated in FIGS. 1A and 1B. Further, the second reflection portion 103 may have a shape including a convex surface or may be in the shape of a flat plate. Further, in the case of using a reflection mirror in the shape of a flat plate as the second reflection portion 103, it is desirable to dispose between the active medium 101 and the second reflection portion 103 a lens having a function of collecting at the active medium 101 the light reflected by the second reflection portion 103, as in the case of the first reflection portion 102.

The third reflection portion 104 has a reflectance of 90.0% or higher with respect to the wavelength range of light emitted from the semiconductor lasers 105. A DBR or metal can be used as the third reflection portion 104. Further, the third reflection portion 104 may be a reflection mirror in the shape of a flat plate as illustrated in FIGS. 1A and 1B, or a concave mirror having a concave surface on the active medium 101 side. Further, the third reflection portion 104 may be disposed at a distance from the active medium 101, but from the point of view of efficient use of light emitted from the semiconductor lasers 105, the third reflection portion 104 is desirably in contact with the active medium 101. Further, the third reflection portion 104 may be formed by applying a multilayer coating or a metal coating directly to the active medium 101.

The fourth reflection portion 109 has a function of transmitting part of light emitted from the semiconductor lasers 105 and reflecting part of the light emitted therefrom. Thus, the fourth reflection portion 109 has a reflectance of 70.0% or higher and 99.0% or lower in the wavelength range of the light emitted from the semiconductor lasers 105. A DBR or metal can be used as the fourth reflection portion 109. Further, the fourth reflection portion 109 may be disposed at a distance from the active medium 101, but from the point of view of efficient use of light emitted from the semiconductor lasers 105, the fourth reflection portion 109 is desirably in contact with the active medium 101. Further, the fourth reflection portion 109 may be formed by applying a multilayer coating or a metal coating directly to the active medium 101.

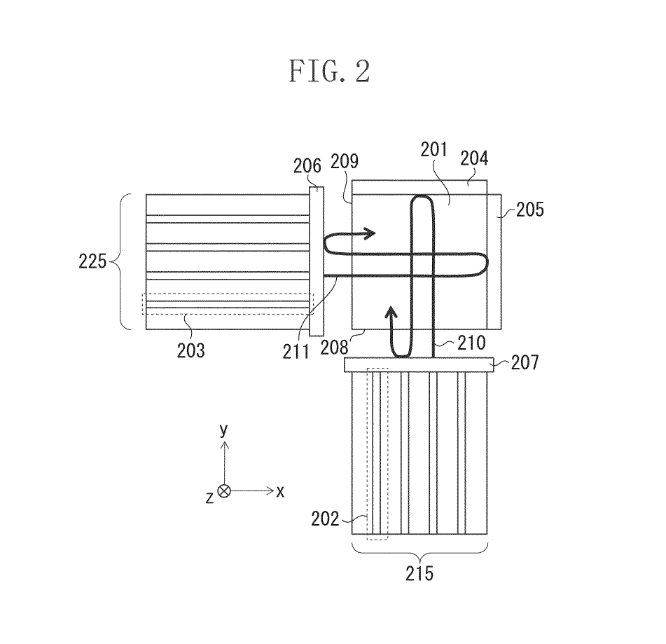

FIG. 2 illustrates an example of a laser apparatus according to a second exemplary embodiment. To achieve higher output of laser light than that in the first exemplary embodiment, the laser apparatus according to the present exemplary embodiment includes a second laser array 225 in addition to a first laser array 215 in which a plurality of semiconductor lasers is disposed in the x-z plane. In the second laser array 225, a plurality of semiconductor lasers is disposed in the y-z plane. Other than this point, the laser apparatus according to the second exemplary embodiment is similar to the laser apparatus according to the first exemplary embodiment. In FIG. 2, the resonance direction of light emitted from an active medium 201 is the z-direction, and illustration of the first and second reflection portions is omitted in FIG. 2.

As in the first exemplary embodiment, the laser apparatus includes a third reflection portion 204 configured to reflect light emitted from the first laser array 215 and transmitted through the active medium 201. Further, the laser apparatus includes a fourth reflection portion 207 between the first laser array 215 and the active medium 201. The fourth reflection portion 207 transmits at least part of light emitted from the first laser array 215 and reflects part of light reflected by the third reflection portion 204 and transmitted through the active medium 201. Light 210 reflected many times by the third reflection portion 204 and the fourth reflection portion 207 is generated and absorbed efficiently by the active medium 201. Further, the fourth reflection portion 207 is disposed across a plurality of semiconductor lasers 202 including respective light-emitting regions of the plurality of semiconductor lasers 202 of the first laser array 215. The plurality of semiconductor lasers 202 is disposed in the same x-z plane. Further, the direction of light emitted from each of the plurality of semiconductor lasers 202 is the y-direction.

As in the first exemplary embodiment, the third reflection portion 204 has a reflectance of 90.0% or higher in the wavelength range of light emitted from the semiconductor lasers 202, and the fourth reflection portion 207 has a reflectance of 70.0% or higher and 99.0% or lower in the wavelength range of light emitted from the semiconductor lasers 202.

Further, the laser apparatus includes a fifth reflection portion 205 configured to reflect light emitted from the second laser array 225 and transmitted through the active medium 201. Further, the laser apparatus includes a sixth reflection portion 206 configured to transmit at least part of light emitted from the second laser array 225 and reflect part of light reflected by the fifth reflection portion 205 and transmitted through the active medium 201. Light 211 reflected many times by the fifth reflection portion 205 and the sixth reflection portion 206 is generated and absorbed efficiently by the active medium 201. Further, the sixth reflection portion 206 is disposed across a plurality of semiconductor lasers 203 including respective light-emitting regions of the plurality of semiconductor lasers 203 of the second laser array 225. The plurality of semiconductor lasers 203 is disposed in the same y-z plane. Further, the direction of light emitted from each of the plurality of semiconductor lasers 203 is the x-direction.

The fifth reflection portion 205 has a reflectance of 90.0% or higher in the wavelength range of light emitted from the semiconductor lasers 203, and the sixth reflection portion 206 has a reflectance of 70.0% or higher and 99.0% or lower in the wavelength range of light emitted from the semiconductor lasers 203.

Further, the semiconductor lasers 202 of the first laser array 215 and the semiconductor lasers 203 of the second laser array 225 may have the same configuration, or may be semiconductor lasers emitting different oscillation wavelengths. In a case where the semiconductor lasers 202 and the semiconductor lasers 203 have the same configuration, the third reflection portion 204 and the fifth reflection portion 205 only need to have the same reflection characteristics, and may be integrally formed of the same member. Similarly, the fourth reflection portion 207 and the sixth reflection portion 206 only need to have the same reflection characteristics, and may be integrally formed of the same member.

Even in a case where the semiconductor lasers 202 and the semiconductor lasers 203 emit light beams of different oscillation wavelengths, the third reflection portion 204 and the fifth reflection portion 205 can share material if the following configuration is employed. More specifically, it is sufficient that a reflection portion having a reflectance of 90.0% or higher in each of the wavelength range of light emitted by the semiconductor lasers 202 and the wavelength range of light emitted by the semiconductor lasers 203 is used as the third reflection portion 204 and the fifth reflection portion 205. Similarly, if a reflection portion having a reflectance of 70.0% or higher and 99.0% or lower in each of the wavelength range of light emitted by the semiconductor lasers 202 and the wavelength range of light emitted by the semiconductor lasers 203 is used as the fourth reflection portion 207 and the sixth reflection portion 206, the fourth reflection portion 207 and the sixth reflection portion 206 can be shared.

Further, it is desirable to apply an AR coating to surfaces 208 and 209 of the active medium 201 that face the first laser array 215 and the second laser array 225, respectively, so as to have high transmittance with respect to the wavelength range of light emitted from the semiconductor lasers 202 and the wavelength range of light emitted from the semiconductor lasers 203.

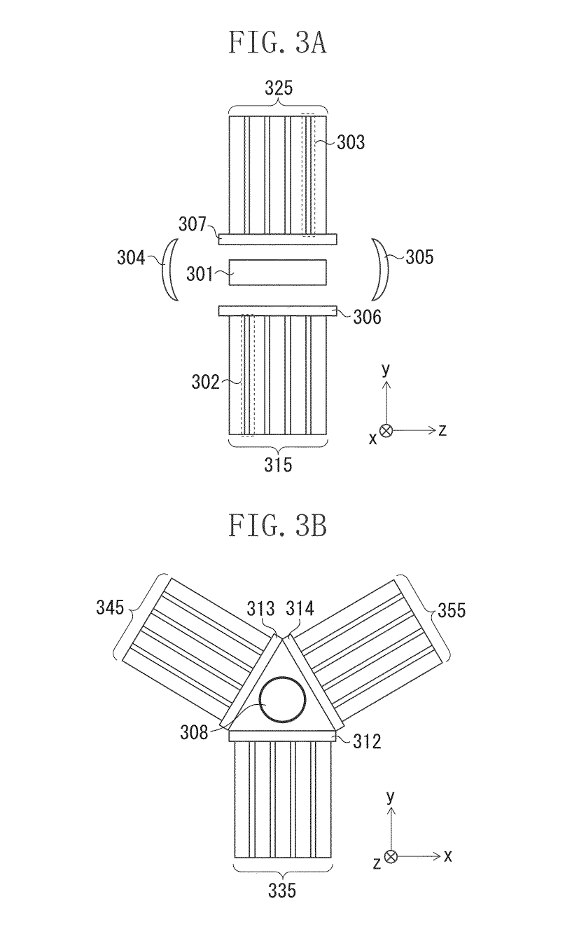

FIGS. 3A and 3B are diagrams each illustrating an example of a laser apparatus according to a third exemplary embodiment. The laser apparatus according to the present exemplary embodiment includes a plurality of laser arrays as in the second exemplary embodiment. However, a reflection portion configured to reflect light emitted from a laser array and transmitted through an active medium also serves as a reflection portion provided at an emission edge of another laser array. The rest of the configuration is similar to that in the second exemplary embodiment.

The laser apparatus illustrated in FIG. 3A includes a third reflection portion 307 configured to reflect light emitted from a first laser array 315, in which a plurality of semiconductor lasers 302 is disposed in the x-z plane, and transmitted through an active medium 301, as in the first exemplary embodiment. Further, the laser apparatus includes a fourth reflection portion 306 disposed between the first laser array 315 and the active medium 301. The fourth reflection portion 306 transmits at least part of light emitted from the first laser array 315 and reflects part of light reflected by the third reflection portion 307 and transmitted through the active medium 301. Thus, light emitted from the first laser array 315 is reflected many times by the third reflection portion 307 and the fourth reflection portion 306 and absorbed by the active medium 301 while being reflected. With this configuration, the active medium 301 emits light, and the light that has a specific wavelength is amplified by a resonance unit constituted by a first reflection portion 304 and a second reflection portion 305 to cause laser oscillation. Further, the fourth reflection portion 306 is disposed across the plurality of semiconductor lasers 302 including respective light-emitting regions of the plurality of semiconductor lasers 302 of the first laser array 315.

Further, the laser apparatus includes a second laser array 325 in which a plurality of semiconductor lasers 303 is disposed in the x-z plane. The second laser array 325 is disposed facing the first laser array 315 so as to sandwich the active medium 301. Light emitted from the second laser array 325 is transmitted through the active medium 301 via the third reflection portion 307 and reflected by the fourth reflection portion 306 described above. Accordingly, the light emitted from the second laser array 325 is also reflected many times by the third reflection portion 307 and the fourth reflection portion 306.

A wavelength range δλ₁ is the wavelength range of light emitted by the semiconductor lasers 302 of the first laser array 315, and a wavelength range δλ₂ is the wavelength range of light emitted by the semiconductor lasers 303 of the second laser array 325. In a case where the wavelength ranges δλ₁ and δλ₂ do not overlap, the third reflection portion 307 and the fourth reflection portion 306 preferably satisfy the following conditions. More specifically, the third reflection portion 307 preferably has a reflectance of 90.0% or higher in the wavelength range δλ₁ and a reflectance of 70.0% or higher and 99.0% or lower in the wavelength range δλ₂. Further, the fourth reflection portion 306 preferably has a reflectance of 70.0% or higher and 99.0% or lower in the wavelength range δλ₁ and a reflectance of 90.0% or higher in the wavelength range δλ₂. In a case where the wavelength ranges δλ₁ and δλ₂ overlap at least partially, the reflectances of the third reflection portion 307 and the fourth reflection portion 306 in the overlapped wavelength range can be appropriately determined from the point of view of the stability of the semiconductor lasers, the output of the semiconductor lasers, the absorption efficiency of the active medium, the thickness of the active medium, etc. The third reflection portion 307 and the fourth reflection portion 306 preferably have a reflectance of at least 70.0% or higher and 99.0% or lower in the overlapped wavelength range. More preferably, the third reflection portion 307 and the fourth reflection portion 306 have a reflectance of 90.0% or higher and 99.0% or lower in the overlapped wavelength range.

As described above, even in a case where a plurality of laser arrays is used, the number of components can still be smaller than that in the second exemplary embodiment by disposing the plurality of laser arrays so as to sandwich the active medium, and appropriately setting the reflectances of the third and fourth reflection portions.

The laser apparatus may include three or more laser arrays. FIG. 3B illustrates an example of a laser apparatus including first, second, and third laser arrays 335, 345, and 355. For example, light emitted from the first laser array 335 enters an active medium 308 via a reflection portion 312. Then, the light transmitted through the active medium 308 is reflected by a reflection portion 313 or 314 and enters the active medium 308 again. The light further transmitted through the active medium 308 is reflected many times by the reflection portions 312, 313, and 314 and absorbed efficiently by the active medium 308. The active medium 308 has a cylindrical rod shape.

Similarly, light emitted from the second laser array 345 and light emitted from the third laser array 355 are reflected many times by the reflection portions 312, 313, and 314 and absorbed efficiently by the active medium 308. With this configuration, the laser arrays and the reflection portions are disposed to surround the active medium 308, so that the absorption efficiency increases.

The reflectance characteristics of the reflection portions 312, 313, and 314 can be determined based on the wavelength ranges of light beams emitted by the respective semiconductor lasers, as in the case of the third reflection portion 307 and the fourth reflection portion 306 in FIG. 3A.

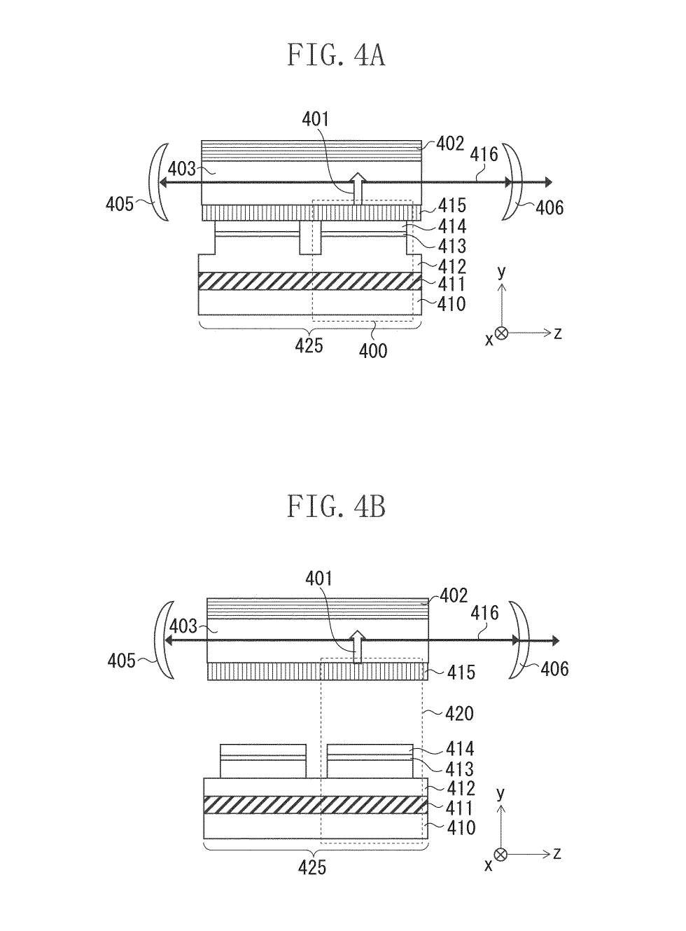

FIGS. 4A and 4B are diagrams each illustrating an example of a laser apparatus according to a fourth exemplary embodiment. An example of a case where semiconductor lasers constituting a first laser array of the present exemplary embodiment are surface emitting lasers is illustrated. The rest of configuration is similar to that in the first exemplary embodiment.

The laser apparatus illustrated in FIG. 4A includes an active medium 403, a first reflection portion 405, and a second reflection portion 406. The first reflection portion 405 and the second reflection portion 406 constitute a resonance unit configured to resonate light 416 emitted from the active medium 403, and the resonance direction is the z-direction. The laser apparatus includes a first laser array 425 including a plurality of surface emitting lasers 400 disposed in the same plane (x-z plane) and configured to emit light 401 for exciting the active medium 403, from the y-direction different from the z-direction, which is the resonance direction.

The surface emitting lasers 400 include a substrate 410, a lower reflection mirror 411 provided on the substrate 410, a lower cladding layer 412, an active layer 413, an upper cladding layer 414, and an upper reflection mirror 415. Further, the substrate 410, the lower reflection mirror 411, part of the lower cladding layer 412, and the upper reflection mirror 415 are shared by the plurality of surface emitting lasers 400.

Further, light emitted from the first laser array 425 and transmitted through the active medium 403 is reflected by a third reflection portion 402. Further, light reflected by the third reflection portion 402 and transmitted through the active medium 403 is reflected by the upper reflection mirror 415 included in the surface emitting lasers 400. In other words, in the present exemplary embodiment, the upper reflection mirror 415 also serves as the fourth reflection portion of the first exemplary embodiment. Light emitted from the first laser array 425 is reflected many times between the third reflection portion 402 and the upper reflection mirror 415 and absorbed efficiently by the active medium 403.

The surface emitting lasers 400 have a mesa structure, and the active layer 413 and the upper cladding layer 414 of two adjacent surface emitting lasers 400 are separated by the mesa structure. The upper reflection mirror 415 is disposed across the two adjacent surface emitting lasers 400 so that the upper reflection mirror 415 is shared by the two adjacent surface emitting lasers 400. In other words, the upper reflection mirror 415, which also serves as the fourth reflection portion, is disposed not only on the light-emitting regions of the plurality of surface emitting lasers 400 but also on an area between the surface emitting lasers. This facilitates manufacturing. Furthermore, emitted light is prevented from returning to the inside of the surface emitting lasers 400, so that the operation stability of the surface emitting lasers 400 can be improved.

DBRs can be used as the lower reflection mirror 411 and the upper reflection mirror 415. Other than DBRs, a diffraction grating having a periodic refractive index distribution in the in-plane direction such as a high index contrast grating (HCG) can be used as the lower reflection mirror 411 and the upper reflection mirror 415. In this case, it is desirable to design and dispose the diffraction gratings in such a manner that most of light diffracted by diffractive elements is diffracted in a direction in which the light is returned to the surface emitting lasers 400.

While the surface emitting lasers 400 illustrated in FIG. 4A are so-called VCSELs, the surface emitting lasers 400 are not limited to the VCSELs. As illustrated in FIG. 3B, vertical external cavity surface emitting lasers (VECSELs) 420 may be used as the semiconductor lasers. The difference between the VECSELs 420 and the VCSELs 400 is the presence/absence of a space between the upper cladding layer 414 and the upper reflection mirror 415.

The surface emitting lasers can have a higher degree of integration in the in-plane direction than the edge emitting lasers, so that the active medium can be excited with a more uniform excitation density distribution.

Further, the present exemplary embodiment may be combined with the second exemplary embodiment and/or the third exemplary embodiment to provide configuration including a plurality of laser arrays.

The material system of the surface emitting lasers 400 can be selected according to the absorption wavelength range of the active medium 403 as described above. For example, in the case of using an alexandrite crystal as the active medium 403, a GaN based material can be used as a material of the surface emitting lasers 400. Specifically, GaN can be used as the substrate 410, a DBR in which GaN and AlGaN each having an optical thickness of λ/4 are alternately stacked can be used as the lower reflection mirror 411, and GaN can be used as the lower cladding layer 412 and the upper cladding layer 414. Further, a quantum well structure of InₓGa₁₋ₓN and GaN can be used as the active layer 413. The quantum well structure may be a single quantum well structure or a multiple quantum well structure. Further, instead of a combination of GaN and AlGaN, a combination of InGaN and AlGaN may be used as the lower reflection mirror 411.

A DBR made of the same combination of materials as that of the lower reflection mirror 411 or a DBR made of a dielectric material may be used as the upper reflection mirror 415. For example, a DBR in which SiO₂ and Ta₂O₅ each having an optical thickness of λ/4 are alternately stacked can be used as the upper reflection mirror 415. Besides SiO₂ and Ta₂O₅, zirconium dioxide (ZrO₂), silicon nitride (SiₓN_{y}), titanium oxide (TiₓO_{y}), MgF₂, CaF₂, BaF₂, Al₂O₃, LiF, etc. can be used as a DBR of the upper reflection mirror 415.

The lower reflection mirror 411 has a reflectance of 99.9% or higher in the wavelength range of light emitted by the surface emitting lasers 400. On the other hand, the upper reflection mirror 415 has a reflectance of 90.0% or higher and 99.8% or lower in the wavelength range of light emitted by the surface emitting lasers 400. The reflectance of the upper reflection mirror 415 is lower than that of the lower reflection mirror 411 because light is emitted from the surface emitting lasers 400. Further, the upper reflection mirror 415 preferably has a reflectance of 99.0% or higher and 99.8% or lower. The reflectances of the reflection mirrors including the DBRs can be adjusted by adjusting a combination of a pair of materials to be used and the number of pairs. For example, in a case where the lower reflection mirror 411 and the upper reflection mirror 415 use the same pair of materials, the reflectances specified above can be satisfied by adjusting the number of pairs in the lower reflection mirror 411 to be larger than the number of pairs in the upper reflection mirror 415.

Further, the surface emitting lasers 400 may generate laser oscillation by a photoexcitation method or a current injection method. In the latter case, an electrode for injecting an electron or a hole can be provided, and a donor and an acceptor may be doped to the lower cladding layer 412 and the upper cladding layer 414, respectively, to transport an electron and a hole to the active layer 413.

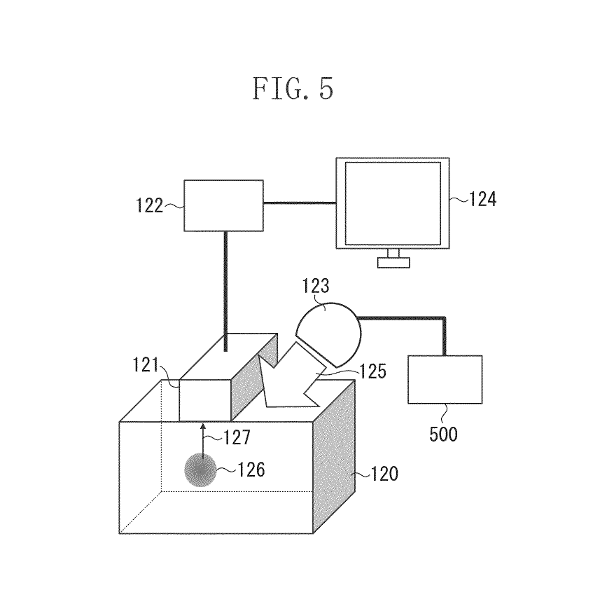

In a fifth exemplary embodiment, an information acquisition apparatus using one of the laser apparatuses according to the first to fourth exemplary embodiments will be described with reference to FIG. 5. A photoacoustic apparatus will be described as an example of the information acquisition apparatus. The photoacoustic apparatus includes a laser apparatus 500, a probe 121, and an acquisition unit 122. The probe 121 detects an elastic wave generated by irradiation of a subject 120 with light emitted by the laser apparatus 500 and converts the detected elastic wave into an electrical signal. The acquisition unit 122 acquires information about optical characteristics of the subject 120 based on the electrical signal. Further, the photoacoustic apparatus includes an optical system 123 configured to irradiate the subject 120 with light emitted by the laser apparatus 500. Further, the photoacoustic apparatus may include a display unit 124 configured to display information acquired by the acquisition unit 122.

Light emitted by the laser apparatus 500 is radiated as pulse light 125 onto the subject 120 via the optical system 123. Then, a photoacoustic wave 127 is generated by a light absorber 126 in the subject 120 due to the photoacoustic effect. The probe 121 detects the photoacoustic wave 127 propagating in the subject 120 to acquire a time-series electrical signal. Then, the acquisition unit 122 acquires information about the inside of the subject 120 based on the time-series electrical signal and displays the information about the inside of the subject 120 on the display unit 124.

As the wavelength of light that can be emitted by the laser apparatus 500, it is desirable to use a wavelength at which the light can propagate to the inside of the subject 120. Specifically, in a case where the subject 120 is a living subject, a preferable wavelength is 500 nm or longer and 1200 nm or shorter. However, in the case of acquiring information about optical characteristics of living subject tissue that is relatively close to a surface of the living subject, it is possible to use a wider wavelength range, e.g., 400 nm or longer and 1600 nm or shorter, than the wavelength range specified above.

The information about optical characteristics of a subject includes the initial acoustic pressure of the photoacoustic wave, optical energy absorption density, absorption coefficient, concentration of a substance constituting the subject, etc. The concentration of a substance refers to oxygen saturation, oxyhemoglobin concentration, deoxyhemoglobin concentration, total hemoglobin concentration, etc. The total hemoglobin concentration is the sum of the oxyhemoglobin concentration and the deoxyhemoglobin concentration. Further, in the present exemplary embodiment, the information about optical characteristics of a subject may be not numerical data but distribution information on positions in the subject. More specifically, the acquisition unit 122 may acquire distribution information such as absorption coefficient distribution and oxygen saturation distribution as the information about optical characteristics of a subject.

### Example 1

Example 1 will describe a configuration example of the laser apparatus according to the fourth exemplary embodiment illustrated in FIG. 4A. The laser apparatus according to Example 1 includes a laser array 425, which is an excitation light source, a first reflection portion 405, a second reflection portion 406, an active medium 403, and a third reflection portion 402. The first reflection portion 405 and the second reflection portion 406 are disposed to face each other via the active medium 403 and constitute a resonator for laser oscillation.

The laser array 425 includes a plurality of VCSELs 400 arranged in an array. The VCSELs 400 includes a substrate 410, a lower reflection mirror 411, a lower cladding layer 412, an active layer 413, an upper cladding layer 414, and an upper reflection mirror 415. The upper reflection mirror 415 also serves as a fourth reflection portion configured to transmit and reflect part of light emitted from the laser array 425. In Example 1, the upper reflection mirror 415 is formed to be in direct contact with the active medium 403. Further, the upper reflection mirror 415 is disposed across the plurality of VCSELs 400 including light-emitting regions of the plurality of VCSELs 400.

The VCSELs 400 in Example 1 are made of a nitride semiconductor. The substrate 410 includes an n-type GaN substrate, and the lower cladding layer 412 and the upper cladding layer 414 include n-type GaN and p-type GaN, respectively. The active layer 413 has a multiple quantum well structure using a nitride semiconductor material, and a well layer and barrier layer of the quantum well structure are InₓGa₁₋ₓN and GaN, respectively, where x=0.1. The bandgap of the well layer is smaller than the bandgaps of the barrier layer, the lower cladding layer 412, and the upper cladding layer 414. The active layer 413 emits light by the injection of a carrier.

The lower reflection mirror 411 includes a nitride semiconductor DBR in which 60 cycles of GaN and AlGaN each having an optical thickness of λ/4 are alternately stacked.

The upper reflection mirror 415 includes a dielectric DBR in which 13 cycles of SiO₂ and Ta₂O₅ each having an optical thickness of λ/4 are alternately stacked. The other portions from the lower reflection mirror 411 to the upper cladding layer 414 are formed by performing a crystal growth method on a GaN substrate and patterning processing by a semiconductor process.

To cause laser light, i.e., excitation light, from the VCSELs 400 to be emitted from the upper reflection mirror 415 side, the upper reflection mirror 415 has a reflectance of about 99.0% in the wavelength range of laser light from the VCSELs 400. Further, the lower reflection mirror 411 has a reflectance of about 99.9% in the wavelength range of laser light from the VCSELs 400. The lower reflection mirror 411 and the upper reflection mirror 415 are designed to exhibit the reflectances specified above with respect to the wavelength range width of 20 nm with a central wavelength of 400 nm of laser light from the VCSELs 400. Light is emitted from the active layer 413 by carrier injection and resonated between the lower reflection mirror 411 and the upper reflection mirror 415 and amplified, and excitation light that is laser light having a central wavelength of 400 nm is emitted toward the active medium 403 in a vertical direction with respect to a surface of the upper reflection mirror 415.

The first reflection portion 405 and the second reflection portion 406 are disposed facing each other via the active medium 403 so as to form a pair of reflection mirrors. The active medium 403 is an alexandrite crystal having a slab shape with a thickness of 2 mm. The oscillation wavelength range of the alexandrite crystal is 700 nm to 850 nm. The first reflection portion 405 is a reflection mirror having a reflectance of 99.9% or higher in the wavelength range, and the second reflection portion 406 is a reflection mirror having a reflectance of about 90.0% in the wavelength range, i.e., so-called an output coupler. Light emitted from the excited alexandrite crystal is resonated in the resonator of the laser apparatus, and laser light that is sufficiently excited and oscillated in the solid-state laser resonator to exceed an oscillation threshold value is output from the output coupler to the outside of the solid-state laser resonator.

The light 401 output from the upper reflection mirror 415 of the laser array 425 enters and is absorbed by the active medium 403. In a case where the active medium 403 has a slab shape, excitation light is not sufficiently absorbed while propagating once in the thickness direction, and most of the excitation light is transmitted. In Example 1, the third reflection portion 402 is provided by vapor-depositing Au (gold) directly on the active medium 403, so that the light transmitted through the active medium 403 can be reflected by the third reflection portion 402 to enter the active medium 403 again. Even if part of the light having entered the active medium 403 again is transmitted again, the part of the light is reflected by the upper reflection mirror 415 (fourth reflection mirror) of the laser array 425 and enters the active medium 403.

As described above, the light emitted from the laser array 425 goes and returns in the active medium 403 by being reflected by the third reflection portion 402 and the upper reflection mirror 415 and is confined within the active medium 403, so that the active medium 403 can be excited efficiently.

Further, the upper reflection mirror 415 serving also as the fourth reflection portion is disposed across the plurality of VCSELs 400 including the light-emitting regions of the plurality of VCSELs 400. Thus, returned light is less likely to occur in the VCSELs 400, so that the operation of the VCSELs 400 can be prevented from becoming unstable.

Further, the third reflection portion 402 is a deposition film of Au (gold) and is connected to an external heat sink. This enables efficient removal of heat generated in the active medium 403 or enables the temperature of the active medium 403 to be controlled.

### Example 2

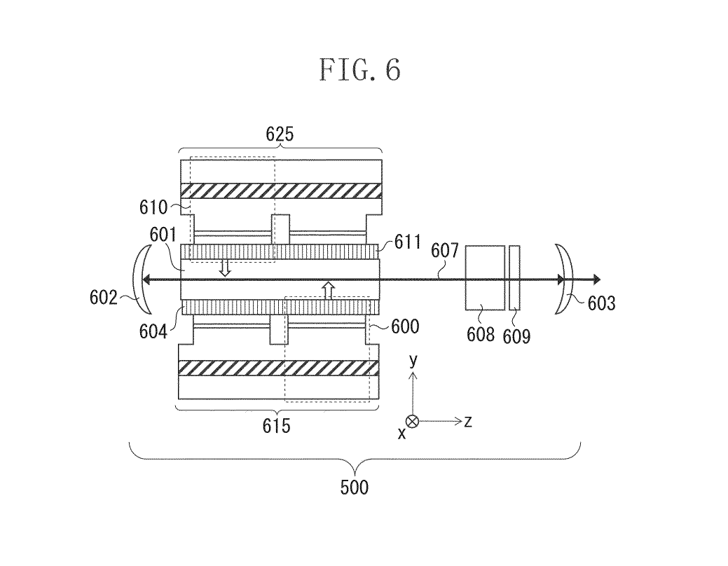

Example 2 will describe a configuration example of the laser apparatus illustrated in FIG. 6 according to a combination of the third and fourth exemplary embodiments. Specifically, the laser apparatus according to Example 2 includes two laser arrays similar to those in Example 1, and an active medium similar to that in Example 1 is sandwiched between the two laser arrays and excited. The following describes differences from Example 1.

The laser apparatus according to Example 2 includes a first laser array 615, a second laser array 625, a first reflection portion 602, a second reflection portion 603, and an active medium 601. A specific wavelength of light 607 emitted from the active medium 601 is amplified by a resonator constituted by the first reflection portion 602 and the second reflection portion 603 to cause laser oscillation of the laser apparatus. A plurality of VCSELs 600 of the first laser array 615 includes a first upper reflection mirror 604. Further, a plurality of VCSELs 610 of the second laser array 625 includes a second upper reflection mirror 611.

The second upper reflection mirror 611 corresponds to the third reflection portion and has a function of reflecting light emitted from the plurality of VCSELs 600 of the first laser array 615 and transmitted through the active medium 601. Further, the second upper reflection mirror 611 also corresponds to the fourth reflection portion and has a function of transmitting part of light emitted from the plurality of VCSELs 610 of the second laser array 625 and reflecting part of light reflected by the first upper reflection mirror 604 and transmitted through the active medium 601.

On the other hand, the first upper reflection mirror 604 corresponds to the fourth reflection portion and has a function of transmitting part of light emitted from the plurality of VCSELs 600 of the first laser array 615 and reflecting part of light reflected by the second upper reflection mirror 611 and transmitted through the active medium 601. Further, the first upper reflection mirror 604 also corresponds to the third reflection portion and has a function of reflecting light emitted by the plurality of VCSELs 610 of the second laser array 625 and transmitted through the active medium 601.

The first upper reflection mirror 604 and the second upper reflection mirror 611 use DBRs similar to those in Example 1. It should be noted, however, that the first upper reflection mirror 604 and the second upper reflection mirror 611 each have a reflectance of about 99.5% in the wavelength range of laser light from the VCSELs 600 and 610. This enables laser oscillation of the VCSELs while decreasing the amount of light returning to the VCSELs 600 and 610.

Further, the first upper reflection mirror 604 is disposed across the plurality of VCSELs 600 including the light-emitting regions of the plurality of VCSELs 600. The second upper reflection mirror 611 is disposed across the plurality of VCSELs 610 including the light-emitting regions of the plurality of VCSELs 610.

Further, the laser apparatus according to Example 2 includes a Q switch 608 and a Brewster window 609 in a resonance unit constituted by the first reflection portion 602 and the second reflection portion 603. The Q switch 608 includes an electrical optical element. The Brewster window 609 defines polarization. The Q switch 608 maintains a Q-value at a low value to restrain oscillation until a significantly large number of atoms in the active medium 601 enter an excited state, and after the number of atoms in the excited state becomes sufficiently large, the Q switch 608 increases the Q-value again to cause oscillation to emit giant pulses.

As described above, a plurality of excitation light sources is used to enable efficient excitation of the active medium. Further, since the first upper reflection mirror 604 and the second upper reflection mirror 611 of the plurality of VCSELs 600 and 610 also serve as the third reflection portion and the fourth reflection portion, the number of components can be reduced. Further, since the first upper reflection mirror 604 and the second upper reflection mirror 611 are disposed across the plurality of VCSELs 600 and 610 including the light-emitting regions of the plurality of VCSELs 600 and 610, respectively, returned light is less likely to occur in the VCSELs 600 and 610, so that the operations of the VCSELs 600 and 610 can be prevented from becoming unstable.

With a laser apparatus according to an exemplary embodiment of the present invention, a laser apparatus that improves the operation stability of semiconductor lasers being an excitation light source, and the absorption efficiency of an active medium with respect to excitation light can be obtained.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2014-203271, filed Oct. 1, 2014, which is hereby incorporated by reference herein in its entirety.

What is claimed is:

1. A laser apparatus comprising:
an active medium;
a resonance unit including a first reflection portion and a second reflection portion which are configured to resonate light emitted from the active medium;
a first laser array including a plurality of semiconductor lasers configured to emit light for exciting the active medium from a direction different from a resonance direction of the resonance unit;
a third reflection portion configured to reflect at least part of light emitted from the first laser array and transmitted through the active medium; and
a fourth reflection portion disposed between the active medium and the first laser array and configured to transmit at least part of light emitted from the first laser array, and to reflect at least part of light reflected by the third reflection portion and transmitted through the active medium,
wherein the fourth reflection portion is disposed across the plurality of semiconductor lasers including respective light-emitting regions of the plurality of semiconductor lasers of the first laser array.

2. The laser apparatus according to claim 1, wherein the fourth reflection portion constitutes a part of the semiconductor lasers of the first laser array.

3. The laser apparatus according to claim 1, further comprising:
a second laser array including a plurality of semiconductor lasers and being different from the first laser array; and
a fifth reflection portion configured to reflect at least part of light emitted from the second laser array and transmitted through the active medium.

4. The laser apparatus according to claim 3, further comprising a sixth reflection portion configured to transmit at least part of light emitted from the second laser array, and to reflect at least part of light reflected by the fifth reflection portion and transmitted through the active medium,
wherein the sixth reflection portion is disposed across the plurality of semiconductor lasers of the second laser array including respective light-emitting regions of the plurality of semiconductor lasers of the second laser array.

5. The laser apparatus according to claim 4, wherein the fifth reflection portion also serves as the fourth reflection portion, and
wherein the sixth reflection portion also serves as the third reflection portion.

6. The laser apparatus according to claim 5, wherein the first laser array and the second laser array are disposed to enclose the active medium from at least opposite sides thereof.

7. The laser apparatus according to claim 1, wherein the active medium has a rod shape, and
wherein a long axis direction of the rod shape is the resonance direction.

8. The laser apparatus according to claim 1, wherein the active medium has a slab shape, and
wherein light emitted from the first laser array enters a largest surface of the slab shape.

9. The laser apparatus according to claim 1, wherein the fourth reflection portion is in contact with the active medium.

10. The laser apparatus according to claim 1, wherein the first reflection portion and the second reflection portion are in contact with the active medium.

11. The laser apparatus according to claim 1, wherein the fourth reflection portion includes a multilayer in which a high refractive index layer and a low refractive index layer are alternately stacked.

12. The laser apparatus according to claim 1, wherein the semiconductor lasers of the first laser array are edge emitting lasers.

13. The laser apparatus according to claim 12, wherein the fourth reflection portion has a reflectance of 70.0% or higher and 99.0% or lower in a wavelength range of light emitted by the first laser array.

14. The laser apparatus according to claim 1, wherein the semiconductor lasers are vertical cavity surface emitting lasers.

15. The laser apparatus according to claim 14, wherein the fourth reflection portion has a reflectance of 90.0% or higher and 99.8% or lower in a wavelength range of light emitted by the first laser array.

16. The laser apparatus according to claim 14, wherein the vertical cavity surface emitting laser includes a pair of reflection mirrors and an active layer, and
wherein one of the pair of reflection mirrors is closer to the active medium and also serves as the fourth reflection portion.

17. The laser apparatus according to claim 1, wherein the semiconductor lasers of the first laser array are external cavity lasers.

18. The laser apparatus according to claim 1, wherein each of the first reflection portion and the second reflection portion has a shape including a concave surface toward the active medium.

19. A laser apparatus comprising:
an active medium;
a resonance unit including a first reflection portion and a second reflection portion which are configured to resonate light emitted from the active medium;
a plurality of laser arrays each including a plurality of semiconductor lasers configured to emit light for exciting the active medium from a direction different from a resonance direction of the resonance unit;
each laser array including a reflection portion configured to reflect at least part of light emitted from a respective laser array and transmitted through the active medium; and
each laser array including a semi-transmissive portion disposed between the active medium and the respective laser array and configured to transmit at least part of light emitted from the respective laser array, and to reflect at least part of the light transmitted through the active medium,
wherein the reflection portion of each laser array is disposed across the plurality of semiconductor lasers thereof including respective light-emitting regions of the plurality of semiconductor lasers.

20. An information acquisition apparatus comprising:
a laser apparatus including:
an active medium;
a resonance unit including a first reflection portion and a second reflection portion which are configured to resonate light emitted from the active medium;
a first laser array including a plurality of semiconductor lasers configured to emit light for exciting the active medium from a direction different from a resonance direction of the resonance unit;
a third reflection portion configured to reflect at least part of light emitted from the first laser array and transmitted through the active medium; and
a fourth reflection portion disposed between the active medium and the first laser array and configured to transmit at least part of light emitted from the first laser array, and to reflect at least part of light reflected by the third reflection portion and transmitted through the active medium,
wherein the fourth reflection portion is disposed across the plurality of semiconductor lasers including respective light-emitting regions of the plurality of semiconductor lasers of the first laser array;
a probe configured to detect an elastic wave generated by irradiation of a subject with light emitted by the laser apparatus, and to convert the detected elastic wave into an electrical signal; and
an acquisition unit configured to acquire information about an optical characteristic of the subject based on the electrical signal.
